(19) United States
(12) Patent Application Publication
(10) Pub. No.: US 2024/0337606 A1
(43) Pub. Date: Oct. 10, 2024

(54) PARALLEL SCANNING OVERLAY METROLOGY WITH OPTICAL META-SURFACES

(71) Applicant: KLA Corporation, Milpitas, CA (US)

(72) Inventors: Andrew V. Hill, Sunriver, OR (US); Jonathan Madsen, Los Altos, CA (US); Ido Dolev, Milpitas, CA (US); Daria Negri, Nesher (IL); Yuval Lubashevsky, Haifa (IL)

(21) Appl. No.: 18/624,444

(22) Filed: Apr. 2, 2024

Related U.S. Application Data
(60) Provisional application No. 63/457,285, filed on Apr. 5, 2023.

(51) Int. Cl. G01N 21/95

(52) U.S. Cl. CPC G01N 21/9501

(57) ABSTRACT

A device may one or more optical elements configured to direct illumination to a sample and collect sample light from the sample in response to the illumination, where at least one of the one or more optical elements include one or more metasurfaces configured to manipulate at least one of the illumination or sample light using sub-wavelength features, where the sub-wavelength features are smaller than at least some wavelengths in at least one of the illumination or the sample light being manipulated, and where the one or more optical elements provide optical power for at least one of focusing the illumination on the sample or collecting the sample light from the sample.

### CROSS-REFERENCE TO RELATED APPLICATION

The present application claims the benefit under 35 U.S.C. § 119(e) of U.S. Provisional Application Ser. No. 63/457,285, filed Apr. 5, 2023, entitled PARALLEL SCANNING OVERLAY METROLOGY WITH OPTICAL META-SURFACES, naming Andrew V. Hill, Jon Madsen, Ido Dolev, Daria Negri, and Yuval Lubashevsky as inventors, which is incorporated herein by reference in the entirety.

### TECHNICAL FIELD

The present disclosure relates generally to optical metrology and, more particularly, to optical metrology using one or more meta-surfaces.

### BACKGROUND

Optical measurement systems in semiconductor device fabrication environments typically include an optical head with various optical elements configured to direct light to a sample and collect light from the sample to be used in a measurement. Existing optical heads are formed from bulk optical elements such as bulk reflective, refractive, or diffractive optical elements. However, these existing optical heads typically have a footprint that is equal to or larger than a typical semiconductor wafer sample such that only a single optical head may be positioned over a sample. The bulk optical elements within existing optical heads are also relatively expensive and are prone to high degrees of variability. As a result, existing optical metrology systems are limited to a single optical head per system and per sample. However, these limitations place constraints on achievable throughput and cost of ownership of optical measurement systems. There is therefore a need to develop systems and methods to cure the above deficiencies.

### SUMMARY

In embodiments, the techniques described herein relate to a device, including one or more optical elements configured to direct illumination to a sample and collect sample light from the sample in response to the illumination, where at least one of the one or more optical elements include one or more metasurfaces configured to manipulate at least one of the illumination or the sample light using sub-wavelength features, where the sub-wavelength features are smaller than at least some wavelengths in at least one of the illumination or the sample light being manipulated, where the one or more optical elements provide optical power for at least one of focusing the illumination on the sample or collecting the sample light from the sample.

In embodiments, the techniques described herein relate to a device, where at least one of the one or more metasurfaces includes a lens.

In embodiments, the techniques described herein relate to a device, where at least one of the one or more metasurfaces includes a beamsplitter.

In embodiments, the techniques described herein relate to a device, where at least one of the one or more metasurfaces includes one or more beam deflectors.

In embodiments, the techniques described herein relate to a device, where at least one of the one or more metasurfaces includes an objective lens.

In embodiments, the techniques described herein relate to a device, where the objective lens is a multi-surface element formed from at least two metasurfaces of the one or more metasurfaces.

In embodiments, the techniques described herein relate to a device, where the one or more optical elements include one or more bulk optical elements, where at least one of the one or more metasurfaces is formed on a surface of at least one of the one or more bulk optical elements.

In embodiments, the techniques described herein relate to a device, where the one or more metasurfaces include two or more metasurfaces, where at least one of the one or more bulk optical elements includes at least two of the two or more metasurfaces.

In embodiments, the techniques described herein relate to a device, where the one or more optical elements include one or more fused optical elements formed from two or more sub-elements, where at least one of the one or more metasurfaces is formed at an interface of two of the two or more sub-elements.

In embodiments, the techniques described herein relate to a device, where the one or more metasurfaces include two or more metasurfaces, where at least one of the one or more fused optical elements includes at least two of the two or more metasurfaces.

In embodiments, the techniques described herein relate to a device, where the one or more optical elements include a first lens formed as at least one of the one or more metasurfaces and configured to collimate the illumination, where the illumination is incident on the first lens as a diverging beam; an objective lens formed as at least one of the one or more metasurfaces, where the objective lens is configured to direct the illumination to the sample and collect the sample light from the sample; a first grating configured to direct the illumination from the first lens to the objective lens; a second lens formed as at least one of the one or more metasurfaces; and a second grating to receive the sample light from the objective lens and direct the sample light to the second lens.

In embodiments, the techniques described herein relate to a device, where the first lens, the objective lens, the first grating, the second lens, and the second grating are integrated in a fused optical element.

In embodiments, the techniques described herein relate to a device, where the one or more optical elements include an objective lens formed as one of the one or more metasurfaces, where the objective lens is configured to direct the illumination to the sample and collect the sample light from the sample; a first metasurface of the one or more metasurfaces configured collimate the illumination and direct the illumination to the objective lens, where the illumination is incident on the first metasurface as a diverging beam; and a second metasurface of the one or more metasurfaces configured to receive the sample light from the objective lens and focus the sample light.

In embodiments, the techniques described herein relate to a device, where the second metasurface focuses the light to a collection field stop.

In embodiments, the techniques described herein relate to a device, where the objective lens, the first metasurface, and the second metasurface are integrated in a monolithic element.

In embodiments, the techniques described herein relate to a device, where the one or more optical elements include an objective lens formed as at least one of the one or more metasurfaces, where the objective lens is configured to direct the illumination to the sample and collect the sample light from the sample; a first metasurface of the one or more metasurfaces configured collimate the illumination, where the illumination is incident on the first lens as a diverging beam; a second metasurface; and a beamsplitter configured to direct the illumination from the first metasurface to the objective lens and direct the sample light from the objective lens to the second metasurface, where the second metasurface focuses the sample light. to a collection field stop.

In embodiments, the techniques described herein relate to a device, where the second metasurface focuses the light to a collection field stop.

In embodiments, the techniques described herein relate to a device, where the objective lens, the first metasurface, the second metasurface, and the beamsplitter are integrated in a fused optical element.

In embodiments, the techniques described herein relate to a device, where the fused optical element further includes a surface to direct the sample light through from the beamsplitter to the second metasurface via total internal reflection.

In embodiments, the techniques described herein relate to a device, where the one or more optical elements include an objective lens formed as at least one of the one or more metasurfaces, where the objective lens is configured to collect the sample light from the sample; and at least one of the one or more metasurfaces configured to direct the illumination to the sample at an angle outside a numerical aperture of the objective lens.

In embodiments, the techniques described herein relate to a device, where the at least one of the one or more metasurfaces configured to direct the illumination to the sample at an angle outside a numerical aperture of the objective lens directs two or more beams of the illumination to the sample outside the numerical aperture of the objective lens.

In embodiments, the techniques described herein relate to a device, where at least some of the sub-wavelength features in at least one particular metasurface of the one or more metasurfaces are arranged into islands distributed across the particular metasurface.

In embodiments, the techniques described herein relate to a device, where at least one of the sub-wavelength features within the islands, a spacing between the islands, or an orientation of the islands varies across the particular metasurface.

In embodiments, the techniques described herein relate to a device, where a distribution of the sub-wavelength features in at least one particular metasurface of the one or more metasurfaces is uniform across the particular metasurface.

In embodiments, the techniques described herein relate to a device, where at least some of the sub-wavelength features in at least one of the one or more metasurfaces are formed as a blazed feature.

In embodiments, the techniques described herein relate to a device, where at least some of the sub-wavelength features in at least one of the one or more metasurfaces are formed as a grating feature.

In embodiments, the techniques described herein relate to a device, where at least some of the sub-wavelength features in at least one of the one or more metasurfaces are formed as a stepped feature.

In embodiments, the techniques described herein relate to a device, where the one or more metasurfaces include two or more metasurfaces, where at least two of the two or more metasurfaces are formed as a stacked structure.

In embodiments, the techniques described herein relate to a device, where at least one of the one or more metasurfaces directs the illumination to the sample at an angle associated with a numerical aperture of at least 0.7.

In embodiments, the techniques described herein relate to a metrology system, including an illumination source configured to generate illumination; one or more optical sub-systems, where a respective one of the one or more optical sub-systems includes one or more optical elements configured to direct the illumination to a sample and collect sample light from the sample in response to the illumination, where at least one of the one or more optical elements includes one or more metasurfaces configured to manipulate at least one of the illumination or sample light using sub-wavelength features, where the sub-wavelength features are smaller than at least some wavelengths in at least one of the illumination or the sample light, where the one or more optical elements provide optical power for at least one of focusing the illumination on the sample or collecting the sample light from the sample; a one or more detectors configured to generate detection signals based on the sample light collected by the one or more optical sub-systems; and a controller communicatively coupled to the plurality of detectors, where the controller includes one or more processors configured to execute program instructions stored in a memory device, where the program instructions are configured to cause the one or more processors to execute a metrology recipe by generating a plurality metrology of measurements of the sample based on the detection signals from the plurality of detectors.

In embodiments, the techniques described herein relate to a metrology system, where the one or more optical sub-systems include two or more optical sub-systems.

In embodiments, the techniques described herein relate to a metrology system, where a distribution of the two or more optical sub-systems is arranged to provide parallel measurements of features in one or more fields on the sample.

In embodiments, the techniques described herein relate to a metrology system, where the distribution of the two or more optical sub-systems is arranged to provide a single one of the optical sub-systems for at least one of the one or more fields on the sample.

In embodiments, the techniques described herein relate to a metrology system, where the distribution of the two or more optical sub-systems is arranged to provide at least two of the optical sub-systems for at least one of the one or more fields on the sample.

In embodiments, the techniques described herein relate to a metrology system, where at least one of the one or more metasurfaces includes a lens.

In embodiments, the techniques described herein relate to a metrology system, where at least one of the one or more metasurfaces includes a beamsplitter.

In embodiments, the techniques described herein relate to a metrology system, where at least one of the one or more metasurfaces includes one or more beam deflectors.

In embodiments, the techniques described herein relate to a metrology system, where at least one of the one or more metasurfaces includes an objective lens.

In embodiments, the techniques described herein relate to a metrology system, where the objective lens is formed from at least two metasurfaces of the one or more metasurfaces.

In embodiments, the techniques described herein relate to a metrology system, where the one or more optical elements include one or more bulk optical elements, where at least one of the one or more metasurfaces is formed on a surface of at least one of the one or more bulk optical elements.

In embodiments, the techniques described herein relate to a metrology system, where the one or more metasurfaces include two or more metasurfaces, where at least one of the one or more bulk optical elements includes at least two of the two or more metasurfaces.

In embodiments, the techniques described herein relate to a metrology system, where the one or more optical elements include one or more fused optical elements formed from two or more sub-elements, where at least one of the one or more metasurfaces is formed at an interface of two of the two or more sub-elements.

In embodiments, the techniques described herein relate to a metrology system, where the one or more metasurfaces include two or more metasurfaces, where at least one of the one or more fused optical elements includes at least two of the two or more metasurfaces.

In embodiments, the techniques described herein relate to a metrology system, where the one or more optical elements include a single monolithic element.

In embodiments, the techniques described herein relate to a metrology method, including directing illumination to a sample with an optical sub-system including one or more optical elements; collecting sample light from the sample in response to the illumination with the optical sub-system, where at least one of the one or more optical elements includes one or more metasurfaces configured to manipulate at least one of the illumination or the sample light using sub-wavelength features, where the sub-wavelength features are smaller than at least some wavelengths in at least one of the illumination or the sample light, where the one or more optical elements provide optical power for at least one of focusing the illumination on the sample or collecting the sample light from the sample; generating detection signals based on at least a portion of the sample light; and generating one or more metrology measurements of the sample based on the detection signals.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A illustrates a conceptual view illustrating an optical measurement system, in accordance with one or more embodiments of the present disclosure.

FIG. 1B illustrates a conceptual view of an optical sub-system, in accordance with one or more embodiments of the present disclosure.

FIG. 1C illustrates a top view of a first design of a portion of a metasurface, in accordance with one or more embodiments of the present disclosure.

FIG. 1D illustrates a side view of the design in FIG. 1C, in accordance with one or more embodiments of the present disclosure.

FIG. 1E illustrates a top view of a second design of a portion of a metasurface 116, in accordance with one or more embodiments of the present disclosure.

FIG. 1F illustrates a side view of the design in FIG. 1E, in accordance with one or more embodiments of the present disclosure.

FIG. 2A illustrates a conceptual view of an optical sub-system depicted with bulk optical elements for pupil-plane-based measurements, in accordance with one or more embodiments of the present disclosure.

FIG. 2B illustrates a schematic diagram of the optical sub-system of FIG. 2A depicted with metasurfaces formed on multiple bulk optical elements, in accordance with one or more embodiments of the present disclosure.

FIG. 2C illustrates a schematic diagram of the optical sub-system of FIG. 2A depicted with metasurfaces formed on faces and interfaces of a fused optical element, in accordance with one or more embodiments of the present disclosure.

FIG. 2D illustrates a schematic diagram of the optical sub-system of FIG. 2A depicted with metasurfaces formed on faces of a monolithic component, in accordance with one or more embodiments of the present disclosure.

FIG. 2E illustrates a schematic diagram of the optical sub-system of FIG. 2A including achromatic metasurfaces, in accordance with one or more embodiments of the present disclosure.

FIG. 3A illustrates a conceptual view of an optical sub-system, in accordance with one or more embodiments of the present disclosure.

FIG. 3B illustrates a schematic diagram of the optical sub-system 102 of FIG. 3A depicted with metasurfaces formed on a fused optical element, in accordance with one or more embodiments of the present disclosure.

FIG. 4A illustrates a conceptual view of an optical sub-system, in accordance with one or more embodiments of the present disclosure.

FIG. 4B illustrates a schematic diagram of the optical sub-system of FIG. 4A depicted with metasurfaces formed on a fused optical element, in accordance with one or more embodiments of the present disclosure.

FIG. 5 illustrates a conceptual schematic depicting an arrangement of multiple optical sub-systems across a sample for parallel measurements, in accordance with one or more embodiments of the present disclosure.

FIG. 6 illustrates a flow diagram illustrating steps performed in a method for providing an optical measurement, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods providing optical measurements (e.g., metrology measurements, inspection measurements, or the like) using one or more optical elements formed with at least one metasurface. A metasurface may be formed as one or more layers of material with thicknesses and/or features smaller (typically substantially smaller) than wavelengths of light used in an intended application. Such features are referred to herein as sub-wavelength features and may be used to locally manipulate the amplitude, phase, and/or polarization of incident light. In this way, metasurfaces may be formed as phase modulators based on electromagnetic wavefront modulation of light, where the specific properties depend at least in part on the shape and distribution of the sub-wavelength features. As an illustration, the sub-wavelength features may provide discrete phase jumps or transitions based on optical resonance effects.

It is contemplated herein that metasurfaces may be designed to perform the functions of many bulk optical elements typically utilized in an optical head of an optical metrology system such as, but not limited to, a lens (e.g., a collimation lens, an objective lens, or the like), a beamsplitter, a beam deflector, or a stop (e.g., a field stop, an aperture stop, or the like). Further, metasurfaces may be designed to combine multiple functions. As a result, it is contemplated herein that an optical head including one or more metasurfaces may provide a compact platform suitable for illumination of a sample and/or collection of light from a sample.

Some embodiments of the present disclosure are directed to an optical head formed from one or more metasurfaces to manipulate illumination and/or collected light. Some embodiments of the present disclosure are directed to an optical metrology system including one or more optical heads formed from one or more metasurfaces. In some embodiments, an optical metrology system includes two or more optical heads to provide parallel characterization of different regions of a sample, where each of the optical heads includes one or more metasurfaces.

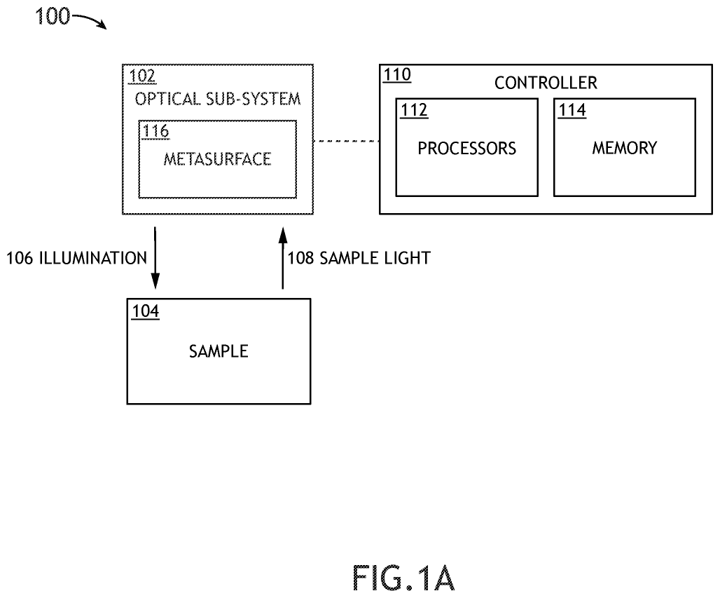

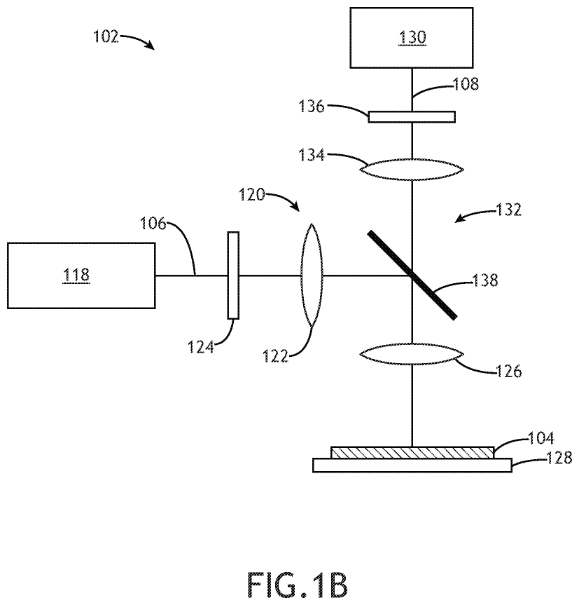

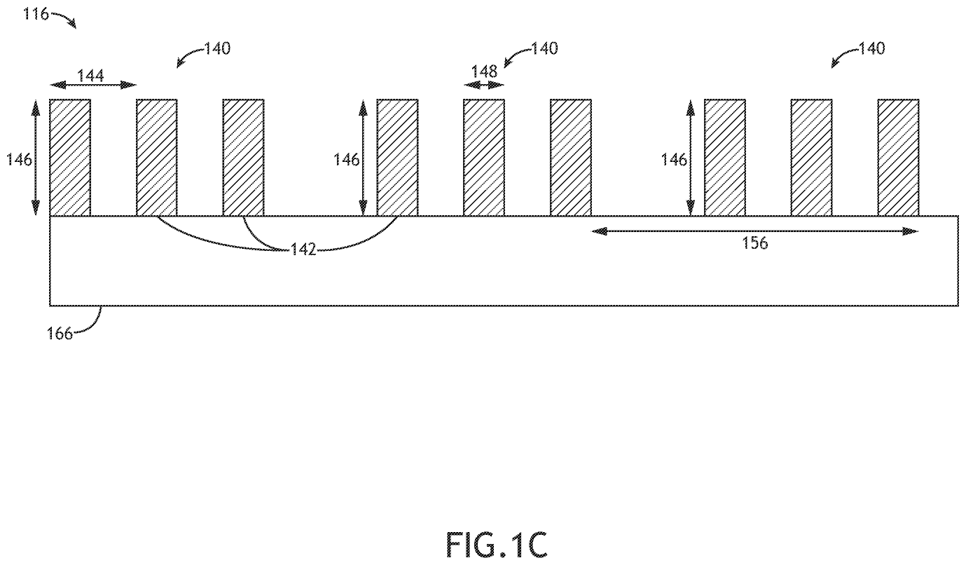

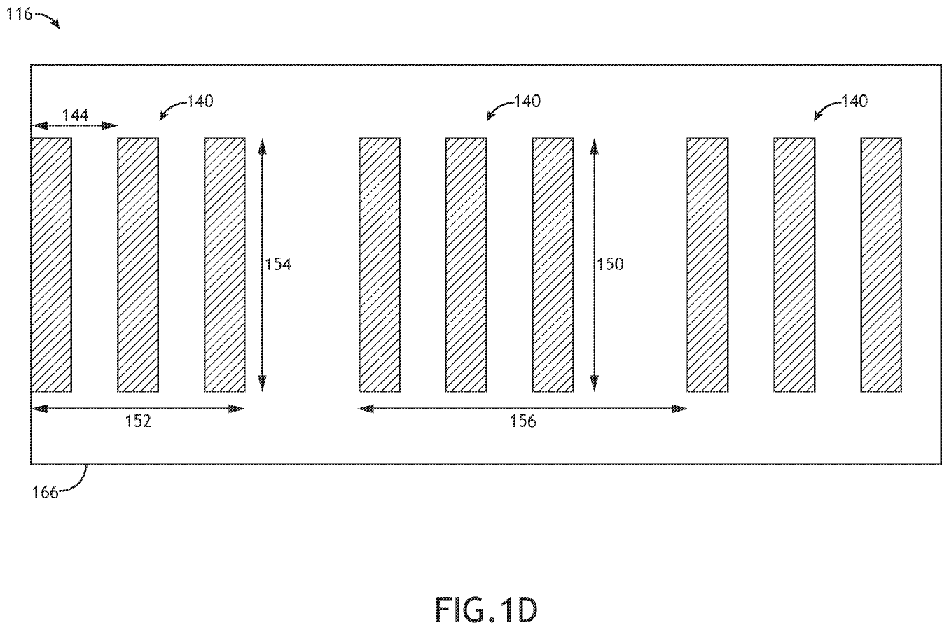

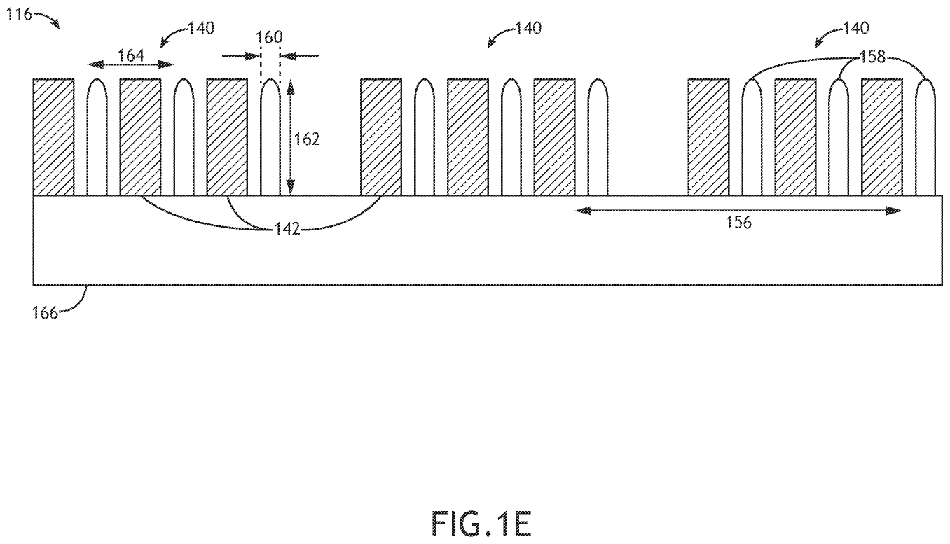

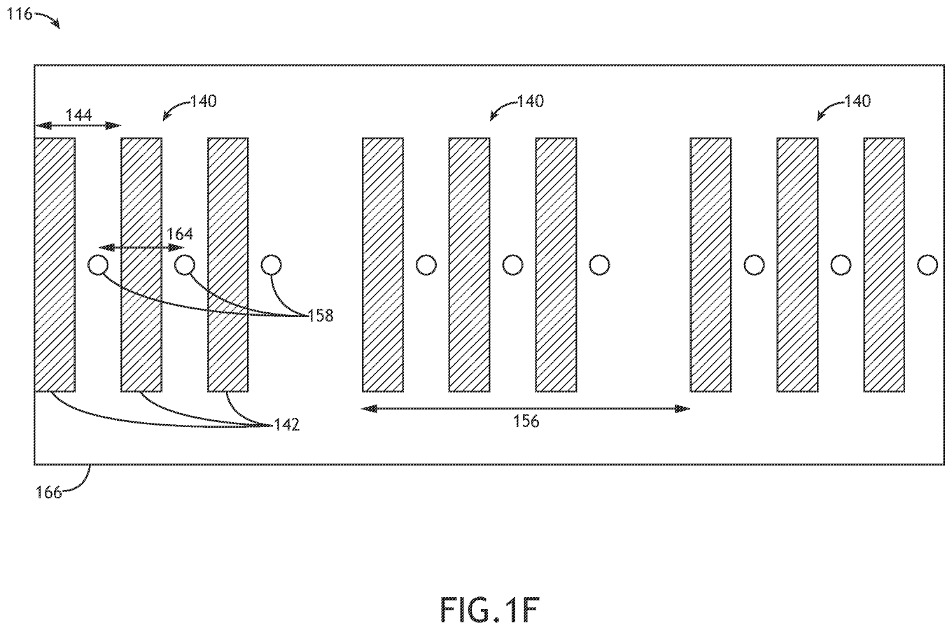

Referring now to FIGS. 1A-6, systems and methods providing optical metrology using metasurfaces are described in greater detail, in accordance with one or more embodiments of the present disclosure.

FIG. 1A is a conceptual view illustrating an optical measurement system 100, in accordance with one or more embodiments of the present disclosure.

In embodiments, the optical measurement system 100 includes an optical sub-system 102 to acquire measurement signals from a sample 104 based on any number of measurement recipes. FIG. 1B is a conceptual view of an optical sub-system 102, in accordance with one or more embodiments of the present disclosure. For example, the optical sub-system 102 may direct illumination 106 to a sample 104 and may further collect light or other radiation emanating from the sample 104 (referred to herein as sample light 108). The optical measurement system 100 may further characterize any portion of the optical measurement system 100 such as, but not limited to, dedicated measurement targets (e.g., overlay targets, metrology targets, or the like) or device features of interest (e.g., in-die features associated with a device being fabricated).

In embodiments, the optical measurement system 100 includes a controller 110. The controller 110 may include one or more processors 112 configured to execute program instructions stored (e.g., maintained) on memory 114, or a memory device. Further, the controller 110 may be communicatively coupled to the optical sub-system 102 or any component therein. In this way, the one or more processors 112 of controller 110 may execute any of the various process steps described throughout the present disclosure either directly or indirectly.

The optical sub-system 102 may include any combination of optical elements suitable for characterizing a sample 104. The optical sub-system 102 may generally operate in an imaging mode or a non-imaging mode. For example, in an imaging mode, individual features on a sample 104 may be resolvable within the illuminated spot on the sample (e.g., as part of a bright-field image, a dark-field image, or the like). Using overlay metrology as a non-limiting example, an overlay measurement may be determined based on relative positions of features associated with different lithographic processes. For instance, a center of symmetry may be determined for each group of features associated with a particular lithographic process such that an overlay measurement may be generated based on differences between the centers of symmetry of different groups of features. By way of another example, the optical sub-system 102 may operate as a scatterometry-based measurement tool in which sample light 108 is analyzed at a pupil plane (e.g., a diffraction plane, a Fourier plane, or the like) to characterize the angular distribution of the sample light 108 generated in response to incident illumination 106. Continuing the example of overlay metrology, an overlay target may have periodic features intended to diffract incident illumination 106 (e.g., into discrete diffraction orders), where an overlay measurement may be generated based on asymmetries between diffraction orders (or asymmetries in the pupil plane more generally).

Further, the optical measurement system 100 may be configurable to generate overlay measurements based on any number of recipes (e.g., measurement recipes, overlay recipes, or the like). An optical measurement system 100 is typically configurable according to a recipe including a set of parameters for controlling the illumination 106 directed to a sample 104 as well as the for the capture of sample light 108. It is recognized herein that different measurement techniques or applications may require different profiles of illumination 106 and/or further utilize different aspects of sample light 108 for a measurement. For example, a recipe may include parameters of the illumination 106 such as, but not limited to, an illumination wavelength, an illumination pupil distribution (e.g., a distribution of illumination angles and associated intensities of illumination at those angles), a polarization of incident illumination, a spatial distribution of illumination, or a sample height. By way of another example, a recipe may include collection parameters associated with sample light 108 used for a measurement such as, but not limited to, a collection pupil distribution (e.g., a desired distribution of angular light from the sample 104 to be used for a measurement and associated filtered intensities at those angles), collection field stop settings to select portions of the sample of interest, polarization of sample light 108 used for a measurement, or wavelength filters controlling the wavelength (or spectrum more generally) of sample light 108 used for a measurement. As another example, a recipe may include parameters associated with the design of features of the sample 104 (e.g., features of a target on the sample 104). As an illustration, a recipe may define various aspects of features on a sample 104 (e.g., on a dedicated target) such as, but not limited to, a number of features, sizes of features, periodicities of features, pitches between features, or the like. In this way, the sample features and the optical sub-system 102 may be co-designed in accordance with a recipe to provide a desired distribution of sample light 108 on one or more detectors that may be indicative of a measurement of interest as well as to provide a series of analysis steps to generate the measurement based on this distribution of sample light 108.

In embodiments, the optical sub-system 102 includes one or more components formed from or otherwise including a metasurface 116, where the metasurface 116 is designed to manipulate illumination 106 directed to a sample 104 and/or sample light 108 collected from the sample 104. Such a metasurface 116 may have any design known suitable for manipulating light (e.g., illumination 106 and/or sample light 108) based at least in part on one or more sub-resolution features. As used herein, the term sub-resolution feature refers to a characteristic of a metasurface 116 having a dimension sufficiently smaller than a wavelength of the light being manipulated that the sub-resolution feature may directly modify the amplitude and/or phase of the light. Put another way, a typical optical element may manipulate light through the accumulation of different amounts of phase delay through different regions of the element, whereas a metasurface 116 may manipulate the amplitude and/or phase of light at a sub-wavelength scale using one or more sub-resolution features. As a result, a metasurface 116 may be designed to provide similar properties as a traditional bulk optical element (e.g., focusing of light, refraction of light, or diffraction of light) but in a more compact package. Further, a metasurface 116 may be designed to manipulate light in ways not possible or practical with a traditional bulk optical element.

The optical measurement system 100 may include any type of metasurface known in the art. For example, a metasurface 116 may be formed using continuous or discrete sub-resolution features. As another example, a metasurface 116 may be formed as a periodic, quasi-periodic, or locally periodic distribution of sub-wavelength features. As an illustration, a metasurface 116 may be formed as, but is not limited to, line/space features forming two-dimensional or three-dimensional grating structures, features with varying height (e.g., stair features, stepped features, blazed features, tilted features, or the like), or pillar features having any shape or distribution. Further, a periodicity of such features may vary across a surface to provide spatially-varying properties on larger spatial scales (e.g., greater than a wavelength of the light being manipulate). As an illustration, a metasurface 116 formed as a lens (e.g., a metalens) may include sub-wavelength features designed to adjust a phase of incident light, where the properties of the sub-wavelength features vary across a surface in a manner designed to provide optical power for operation as a lens.

Additionally, a metasurface 116 may be a reflective element or a transmissive element. Further, the optical measurement system 100 may integrate metasurfaces 116 with any number of traditional optical components (e.g., refractive components, reflective components, transmissive components, diffractive components, or the like).

Referring now to FIGS. 1C-1F, FIGS. 1C-1F include non-limiting examples of sub-wavelength features suitable for forming a metasurface 116.

FIG. 1C illustrates a top view of a first design of a portion of a metasurface 116, in accordance with one or more embodiments of the present disclosure. FIG. 1D illustrates a side view of the design in FIG. 1C, in accordance with one or more embodiments of the present disclosure.

In some embodiments, a metasurface 116 is formed as a series of islands 140 formed as a periodic distribution of sub-wavelength features. For example, FIGS. 1C and 1D depict a configuration where an island 140 includes a one-dimensional grating formed with periodic grating features 142. It is contemplated herein that any of the dimensions of the grating features 142 or an island 140 as a whole may have dimensions smaller than a wavelength of light to be manipulated and may be designed to operate as a metasurface 116. For example, the grating features 142 in FIGS. 1C and 1D may have a pitch 144, a height 146, a width 148, and a length 150, where one or more of these parameters are smaller than a wavelength of the light to be manipulated by the metasurface 116. As another example, various parameters of the islands 140 may be, but are not required to be, smaller than a wavelength of the light to be manipulated by the metasurface 116. For instance, any combination of an island width 152, an island length 154 (e.g., in this case equivalent to the length 150 of a grating feature 142), or a pitch 156 of the islands 140 may be, but is not required to be, smaller than a wavelength of the light to be manipulated by the metasurface 116.

FIGS. 1E and 1F depict another design of a portion of a metasurface 116, in accordance with one or more embodiments of the present disclosure. FIG. 1E illustrates a top view of a second design of a portion of a metasurface 116, in accordance with one or more embodiments of the present disclosure. FIG. 1F illustrates a side view of the design in FIG. 1E, in accordance with one or more embodiments of the present disclosure.

The second design depicted in FIGS. 1E and 1F include islands 140 with the grating features 142 as well as additional pillars 158, which may be, but are not required to be, characterized as assist features. As with the grating features 142, one or more properties of the pillars 158 such as, but not limited to, the diameter 160, height 162, pitch 164, or position relative to the grating features 142 may be smaller than a wavelength of the light to be manipulated by the metasurface 116.

In some embodiments, one or more properties of the islands 140 may vary across the metasurface 116 to provide spatially-varying properties. For example, a pitch 156 between islands 140 and/or an orientation of the islands 140 may vary across the metasurface 116. As another example, a design of the features within the islands 140 may vary across the metasurface 116. For instance, at least one of the pitch 144, the height 146, the width 148, the length 150, or a number of the grating features 142 may vary between islands 140. In another instance, different islands 140 may include different distributions and/or designs of features. As an illustration, a metasurface 116 may some islands 140 with the first design depicted in FIGS. 1C-1D and some islands 140 with the second design depicted in FIGS. 1E-1F, where the distribution of the different designs may be uniform across the metasurface 116 or spatially-varying across the metasurface 116.

Referring generally to FIGS. 1C-1F, the various features of a metasurface 116 may be formed using any materials or combinations of materials. For example, the grating features 142 and/or the pillars 158 may be formed from a high-index material such as, but not limited to, TiO₂. Further, a metasurface 116 may include features formed from multiple materials.

It is contemplated herein that FIGS. 1C-1F are provided solely for illustrative purposes and should not be interpreted as limiting the scope of the present disclosure. For example, a metasurface 116 may have any number or type of features having any design suitable for manipulating light. As another example, FIGS. 1C and 1E depict the grating features 142 and the pillars 158 formed over a substrate 166. However, this is not a requirement. In some embodiments, a metasurface 116 includes additional material surrounding the grating features 142 and/or the pillars 158 to provide such features within a layer with a uniform height, which may be useful for integrating such a metasurface 116 with additional materials and/or at an interface between different materials. In some embodiments, a metasurface 116 is formed from materials in two or more layers such that the metasurface 116 is a multi-layer structure. Further, any number of additional layers may be present above or below the features and/or layers forming a metasurface 116.

In some embodiments, multiple metasurfaces 116 may be fabricated in a stacked configuration. In this case, multiple metasurfaces 116 may be fabricated in overlapping areas in a path of incident light, either directly on top of each other or with intermediate layers between the metasurfaces 116. As an illustration, the optical response of a particular metasurface 116 may depend on the properties of incident light such as, but not limited to, wavelength or polarization. In this case, different metasurfaces 116 designed for different properties may be stacked to provide desired performance characteristics for light with these different properties. For instance, different metasurfaces 116 designed for different wavelengths may be stacked to provide desired performance characteristics for multi-wavelength or broadband light. A metasurface 116 may further be formed using any fabrication technique known in the art such as, but not limited to, additive manufacturing techniques or subtractive manufacturing techniques.

The optical measurement system 100 may include one or more metasurfaces 116 providing any function. For example, the optical sub-system 102 of an optical measurement system 100 may include, but is not limited to, one or more metasurfaces 116 formed as a lens (e.g., a collimation lens, an objective lens, or the like), a beamsplitter, a beam deflector, or a stop (e.g., a field stop, an aperture stop, or the like). Further, in some cases, a metasurface 116 may be designed to combine multiple functions.

In some embodiments, an optical sub-system 102 includes one or more optical heads, where at least one optical head includes at least one metasurface 116 arranged to direct illumination 106 to a sample 104, capture sample light 108 from the sample 104, and/or manipulate any combination of the illumination 106 or the sample light 108. Further, such an optical head may provide a relatively high numerical aperture (e.g., 0.7 or greater) for at least one of focusing the illumination 106 to the sample 104 or collecting the sample light 108. In some cases, the optical head includes an objective lens formed at least in part using one or more metasurfaces 116 providing optical power for operation as a lens (e.g., a metalens) having a numerical aperture of at least 0.7.

Referring again to FIG. 1B, various components of the optical sub-system 102 are now described in greater detail, in accordance with one or more embodiments of the present disclosure. It is contemplated herein that any components or combinations of components depicted in FIG. 1B may be formed as one or more metasurfaces 116. Such metasurfaces 116 may be single-layer or multi-layer metasurfaces 116. Further, multiple components with or without metasurfaces 116 may be integrated into monolithic components (e.g., combined components). In this way, the various separate components depicted in FIG. 1B are merely illustrative and should not be interpreted as limiting the scope of the present disclosure.

In one embodiment, the optical sub-system 102 includes an illumination source 118 configured to generate the illumination 106 in the form of at least one illumination beam. The illumination from the illumination source 118 may include one or more selected wavelengths of light including, but not limited to, ultraviolet (UV) radiation, visible radiation, or infrared (IR) radiation. As an illustration, the wavelengths may be, but are not required to be, in a range of 248-1600 nm. For example, the optical sub-system 102 may include one or more apertures at an illumination pupil plane to divide illumination from the illumination source 118 into one or more beams of illumination 106 or illumination lobes. In this regard, the optical sub-system 102 may provide dipole illumination, quadrupole illumination, or the like. Further, the spatial profile of the beams of illumination 106 on the sample 104 may be controlled by a field-plane stop to have any selected spatial profile.

The illumination source 118 may include any type of illumination source suitable for providing illumination 106. In one embodiment, the illumination source 118 is a laser source. For example, the illumination source 118 may include, but is not limited to, one or more narrowband laser sources, a broadband laser source, a supercontinuum laser source, a white light laser source, or the like. In this regard, the illumination source 118 may provide illumination 106 having high coherence (e.g., high spatial coherence and/or temporal coherence). In another embodiment, the illumination source 118 includes a laser-sustained plasma (LSP) source. For example, the illumination source 118 may include, but is not limited to, a LSP lamp, a LSP bulb, or a LSP chamber suitable for containing one or more elements that, when excited by a laser source into a plasma state, may emit broadband illumination. In another embodiment, the illumination source 118 includes a lamp source. For example, the illumination source 118 may include, but is not limited to, an arc lamp, a discharge lamp, an electrode-less lamp, or the like. In this regard, the illumination source 118 may provide illumination 106 having low coherence (e.g., low spatial coherence and/or temporal coherence).

The illumination source 118 may provide illumination 106 using free-space techniques and/or optical fibers. Further, the illumination source 118 may be included within an optical head (e.g., an optical sub-system 102) or located remotely from an optical head (e.g., an optical sub-system 102). In this way, an optical head (e.g., an optical sub-system 102) may receive illumination 106 from an illumination source 118 using any combination of free-space coupling or optical fibers. Further, the illumination 106 may be provided as a diverging beam, a collimated beam, or a beam having any focal characteristics.

In some embodiments, the illumination source 118 generates multi-lobe illumination 106 by providing light in two or more optical fibers, where light output from each optical fiber is an illumination lobe of the illumination beam. In another embodiment, the illumination source 118 generates multi-lobe illumination 106 by diffracting a light source into two or more diffraction orders, where the illumination lobes of the illumination 106 are formed from at least some of the diffraction orders of the light source. Efficient generation of multiple illumination lobes through controlled diffraction is generally described in U.S. Pat. No. 11,118,903 issued on Sep. 14, 2021, which is incorporated herein by reference in its entirety.

In another embodiment, the optical sub-system 102 directs the illumination beam to the sample 104 via an illumination pathway 120. The illumination pathway 120 may include one or more optical elements suitable for modifying and/or conditioning the illumination beam as well as directing the illumination beam to the sample 104. In one embodiment, the illumination pathway 120 includes one or more illumination-pathway lenses 122 (e.g., to collimate the illumination beam, to relay pupil and/or field planes, or the like). In another embodiment, the illumination pathway 120 includes one or more illumination-pathway optics 124 to shape or otherwise control the illumination beam. For example, the illumination-pathway optics 124 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In another embodiment, the optical sub-system 102 includes an objective lens 126 to focus the illumination beam onto the sample 104 (e.g., an overlay target with overlay target elements located on two or more layers of the sample 104). In another embodiment, the sample 104 is disposed on a sample stage 128 suitable for securing the sample 104 and further configured to position the sample 104 with respect to the illumination beam.

In another embodiment, the optical sub-system 102 includes one or more detectors 130 configured to capture light or other emanating from the sample 104 (e.g., sample light 108) through a collection pathway 132. The collection pathway 132 may include one or more optical elements suitable for modifying and/or conditioning the sample light 108 from the sample 104. In one embodiment, the collection pathway 132 includes one or more collection-pathway lenses 134 (e.g., to collimate the illumination beam, to relay pupil and/or field planes, or the like), which may include, but is not required to include, the objective lens 126. In another embodiment, the collection pathway 132 includes one or more collection-pathway optics 136 to shape or otherwise control the sample light 108. For example, the collection-pathway optics 136 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

A detector 130 may be located at any selected location within the collection pathway 132. In one embodiment, the optical sub-system 102 includes a detector 130 at a field plane (e.g., a plane conjugate to the sample 104) to generate an image of the sample 104. In another embodiment, the optical sub-system 102 includes a detector 130 at a pupil plane (e.g., a diffraction plane) to generate a pupil image. In this regard, the pupil image may correspond to an angular distribution of light from the sample 104 detector 130. For instance, diffraction orders associated with diffraction of the illumination beam from the sample 104 (e.g., an overlay target on the sample 104) may be imaged or otherwise observed in the pupil plane. In a general sense, a detector 130 may capture any combination of reflected (or transmitted), scattered, or diffracted light from the sample 104.

The optical sub-system 102 may generally include any number or type of detectors 130 suitable for capturing light from the sample 104 indicative of overlay. In one embodiment, the detector 130 includes one or more detectors 130 suitable for characterizing a static sample. In this regard, the optical sub-system 102 may operate in a static mode in which the sample 104 is static during a measurement. For example, a detector 130 may include a two-dimensional pixel array such as, but not limited to, a charge-coupled device (CCD) or a complementary metal-oxide semiconductor (CMOS) device. In this regard, the detector 130 may generate a two-dimensional image (e.g., a field-plane image or a pupil-plan image) in a single measurement.

In one embodiment, the detector 130 includes one or more detectors 130 suitable for characterizing a moving sample (e.g., A scanned sample). In this regard, the optical sub-system 102 may operate in a scanning mode in which the sample 104 is scanned with respect to a measurement field during a measurement. For example, the detector 130 may include a 2D pixel array with a capture time and/or a refresh rate sufficient to capture one or more images during a scan within selected image tolerances (e.g., image blur, contrast, sharpness, or the like). By way of another example, the detector 130 may include a line-scan detector to continuously generate an image one line of pixels at a time. By way of another example, the detector 130 may include a time-delay integration (TDI) detector

In another embodiment, the optical sub-system 102 includes a scanning sub-system to scan the sample 104 with respect to the measurement field during a metrology measurement. For example, the sample stage 128 may position and orient the sample 104 within a focal volume of the objective lens 126. In another embodiment, the sample stage 128 includes one or more adjustable stages such as, but not limited to, a linear translation stage, a rotational stage, or a tip/tilt stage. In another embodiment, though not shown, the scanning sub-system includes one or more beam-scanning optics (e.g., rotatable mirrors, galvanometers, or the like) to scan the illumination beam with respect to the sample 104).

The illumination pathway 120 and the collection pathway 132 of the optical sub-system 102 may be oriented in a wide range of configurations suitable for illuminating the sample 104 with the illumination beam and collecting light emanating from the sample 104 in response to the incident illumination beam. For example, as illustrated in FIG. 1B, the optical sub-system 102 may include a beamsplitter 138 oriented such that a common objective lens 126 may simultaneously direct the illumination beam to the sample 104 and collect light from the sample 104. Such a configuration may be referred to as a through-the-lens (TTL) configuration since the illumination 106 is directed to the sample 104 through the same objective lens 126 used to collect sample light 108. By way of another example, the optical sub-system 102 may include optical elements (e.g., illumination-pathway lenses 122) to direct the illumination 106 to the sample 104 and a separate objective lens 126 to collect the sample 104. Such a configuration may be referred to as an outside-the-lens (OTL) configuration.

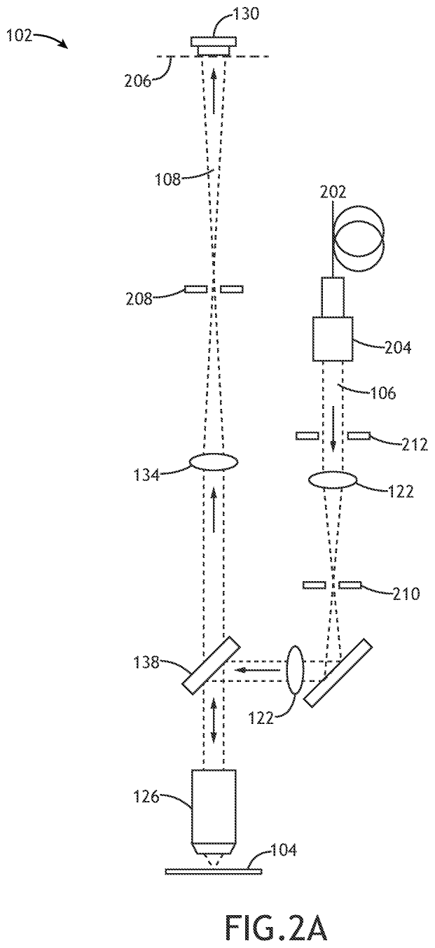

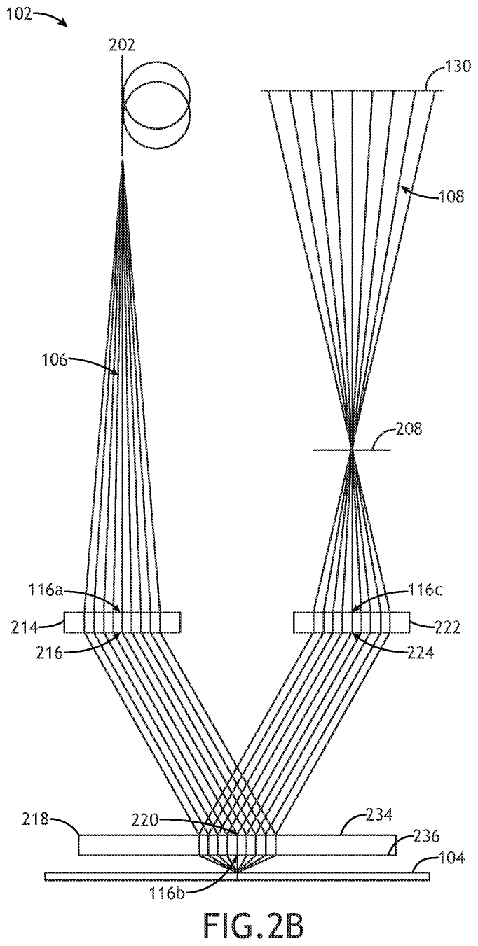

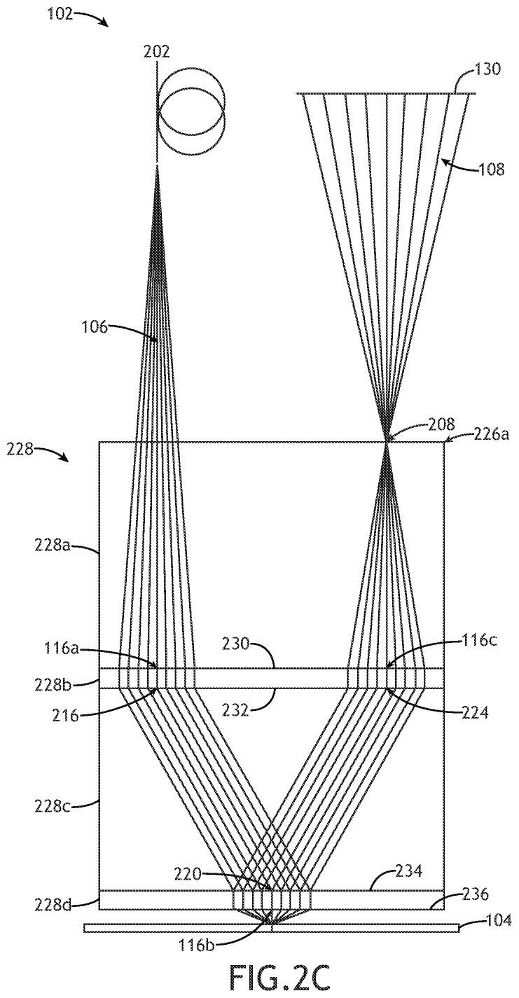

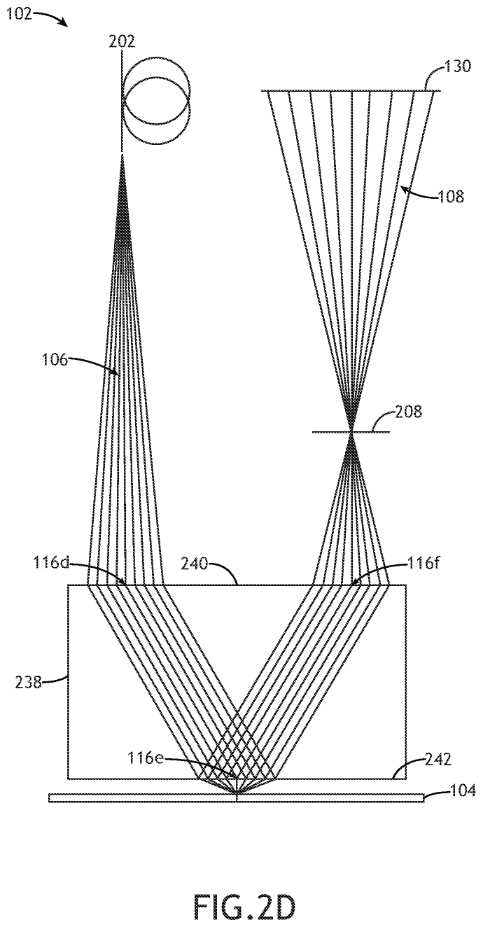

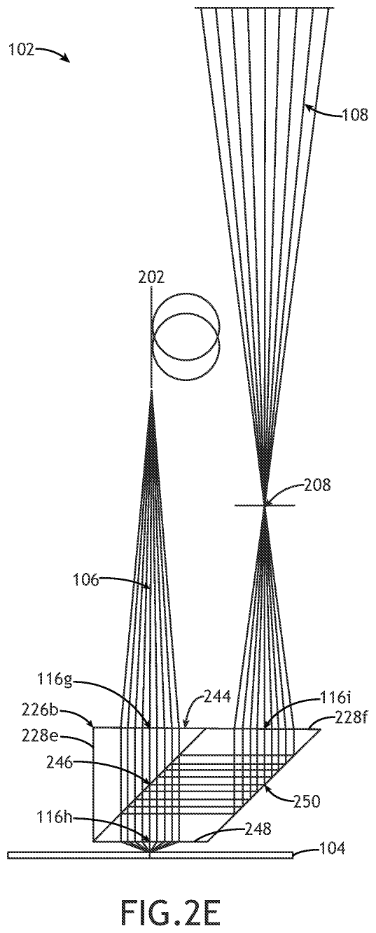

FIGS. 2-4B depict various non-limiting examples of metasurfaces 116 within an optical sub-system 102, in accordance with one or more embodiments of the present disclosure.

FIGS. 2A-2E depict the use of metasurfaces 116 in variations of an optical sub-system 102 suitable for coherent spot scanning measurement applications, in accordance with one or more embodiments of the present disclosure.

FIG. 2A is a conceptual view of an optical sub-system 102 depicted with bulk optical elements for pupil-plane-based measurements, in accordance with one or more embodiments of the present disclosure. FIG. 2A is a variation of FIG. 1B such that all descriptions associated with FIG. 1B extend to FIG. 2A. In particular, FIG. 2A depicts a TTL configuration in which coherent illumination 106 is provided by an optical fiber 202 (e.g., a single mode fiber), collimated by a collimator 204, and directed to a sample 104 via a beamsplitter 138 and an objective lens 126. The optical fiber 202 may be associated with the illumination source 118 (e.g., a fiber-based illumination source 118) or may be a delivery fiber. The objective lens 126 collects sample light 108, which passes through the beamsplitter 138 towards one or more detectors 130 located at a pupil plane 206. FIG. 2A further depicts a field stop 208 in the collection pathway 132, a field stop 210 in the illumination pathway 120, and a stop 212 (e.g., an aperture stop) in the illumination pathway 120. The configuration depicted in FIG. 2A may be suitable for, but is not limited to, coherent diffraction-based measurement techniques utilizing pupil-plane detectors 130. Non-limiting examples of coherent diffraction-based measurement techniques are generally described in U.S. Pat. No. 11,300,405 issued on Apr. 12, 2022, U.S. Patent Publication No. 2023/0314319 published on Oct. 5, 2023; U.S. Patent Publication No. 2023/0314344 published on Oct. 5, 2023, and U.S. Pat. No. 11,796,925 issued on Oct. 24, 2023; which are all incorporated herein by reference in their entireties.

FIGS. 2B-2E depict variations of the second configuration of the optical sub-system 102 in FIG. 2A that incorporate metasurfaces 116.

In some embodiments, the optical sub-system 102 includes one or more bulk optical elements, where a surface of such a bulk optical element includes structures that form a metasurface 116. It is contemplated herein that such bulk optical elements may be formed as thin elements that may be substantially smaller than typical components designed to manipulate light without metasurfaces 116.

FIG. 2B is a schematic diagram of the optical sub-system 102 of FIG. 2A depicted with metasurfaces 116 formed on multiple bulk optical elements, in accordance with one or more embodiments of the present disclosure. In some embodiments, the components in FIG. 2B may form an optical head. In FIG. 2B, the optical sub-system 102 includes a first bulk optical element 214 with a metasurface 116a formed as a lens (e.g., a collimation lens to collimate diverging illumination 106) as well as a first grating 216 to direct collimated illumination 106 towards a second bulk optical element 218 including a grating beamsplitter 220 and a metasurface 116b formed as an objective lens. In this way, the first bulk optical element 214 may be a part of the illumination pathway 120 and may operate as an illumination-pathway lens 122 and an illumination-pathway optic 124. The sample light 108 may then be collected by the metasurface 116b formed as an objective lens and directed by the grating beamsplitter 220 towards a third bulk optical element 222 including a second grating 224 and a metasurface 116c formed as a lens. The metasurface 116c formed as a lens may then focus the sample light 108 through the field stop 208 towards the detector 130 in the pupil plane 206. The third bulk optical element 222 may thus be a part of the collection pathway 132 and may operate as a collection-pathway lens 134 and a collection-pathway optic 136. In some embodiments, the first bulk optical element 214 and the third bulk optical element 222 may have similar designs (e.g., may be complementary devices).

In the configuration depicted in FIG. 2B, metasurfaces 116 are fabricated on various surfaces (e.g., faces) of the first bulk optical element 214, the second bulk optical element 218, and the third bulk optical element 222 to manipulate the illumination 106 and/or the sample light 108. Further, an optical element may include any combination of metasurfaces 116 or other patterned features (e.g., the first grating 216 and the second grating 224).

Table 1 includes various parameters associated with one non-limiting implementation of FIG. 2B, in accordance with one or more embodiments of the present disclosure. It is contemplated herein that such parameters may be suitable for, but not limited to, operation of the 100// as a coherent spot scanning microscope.

TABLE 1

| Wavelength of illumination | 405 | nm |
|---|---|---|
| 106 | | |
| Fiber NA | 0.120 NA 1/e² | |
| Gaussian Truncation | 0.086 | NA |
| Collimation Lens | 11.6 | mm |
| (metasurface 116a) Focal | | |
| Length | | |
| Pitch of gratings 216, 224 | 810 | nm |
| and Beam Splitter Grating | | |
| 220 | | |
| Diffraction Angle of Gratings | 30 | deg |
| 216, 224, 230 | | |
| Meta-Lens Diameters (e.g., | 2.0 | mm |
| metasurfaces 116a, 116c) | | |
| Objective Lens Focal Length | 0.4 | mm |
| (metasurface 116b) | | |
| Objective Working Distance | 0.4 | mm |
| Objective NA | 0.93 | NA |
| Collection Lens | 4.1 | mm |
| (metasurface 116c)Focal | | |
| Length | | |
| Collection Field Stop | 0.15 | mm |
| Diameter | | |
| Pupil Image Diameter | 4.45 | mm |

In some embodiments, the optical sub-system 102 includes one or more fused optical elements, where one or more metasurfaces 116 are formed on one or more surfaces of such a fused optical element and/or on one or more interfaces between sub-components joined together (e.g., with optically-transparent adhesive or any other suitable joining technique) to create such a fused optical element. It is contemplated herein that a fused components may be highly compact, mechanically stable, and fix optical alignment between constituent metasurfaces 116 and/or other features.

FIG. 2C is a schematic diagram of the optical sub-system 102 of FIG. 2A depicted with metasurfaces 116 formed on faces and interfaces of a fused optical element 226a, in accordance with one or more embodiments of the present disclosure. In particular, FIG. 2C depicts a fused optical element 226a formed from four sub-elements 228 (labeled individually as 228a-d). In this configuration, the metasurface 116a formed as a lens and the metasurface 116c formed as a lens are provided at an interface 230 on any combination of sub-elements 228a,b; the first grating 216 and the second grating 224 are provided at an interface 232 on any combination of sub-elements 228b,c; the grating beamsplitter 220 is provided at an interface 234 on any combination of sub-elements 228c,d; and the metasurface 116b formed as a lens is provided at an outer surface 236.

FIG. 2C may thus be conceptualized, but is not limited to, a variation of FIG. 2B in which the first bulk optical element 214 and the third bulk optical element 222 are joined into a common sub-element 228b (though this is merely illustrative and not required), and where the sub-element 228c takes the place of open space between the bulk optical elements 210,214,218. As a result, FIGS. 2B and 2C may provide substantially the same optical performance, but FIG. 2C may provide a more compact package and easier optical alignment. However, FIG. 2C is merely illustrative and should not be interpreted as limiting the scope of the present disclosure.

Additionally, FIG. 2C depicts a configuration in which the sub-element 228a extends to a field plane such that the field stop 208 may be fabricated on a face of the sub-element 228a. However, this is merely illustrative and not required. In some embodiments, the fused optical element 226a does not include the sub-element 228a (e.g., the fused optical element 226a may be formed from sub-elements 228b-d). In this configuration, a separate field stop 208 may be provided if desired.

In some embodiments, a metasurface 116 may provide multiple optical functions (e.g., optical power, diffraction, refraction, or the like). Put another way, a metasurface 116 may manipulate light in a way that replicates the performance of multiple traditional optical elements that manipulate light via accumulation of phase delay or other techniques. For example, a single metasurface 116 may include features designed to provide multiple optical functions. As another example, two or more metasurfaces 116 may be fabricated in a stack (e.g., as a compound metasurface 116) to provide the multiple optical functions. It is contemplated herein that the use of one or more metasurfaces 116 providing multiple optical functions may further simplify and/or shrink a design of an optical sub-system 102 (or a portion thereof).

FIG. 2D is a schematic diagram of the optical sub-system 102 of FIG. 2A depicted with metasurfaces 116 formed on faces of a monolithic component 238, in accordance with one or more embodiments of the present disclosure. In FIG. 2D, the monolithic component 238 is formed as a single uniform element of material with metasurfaces 116d-e on various surfaces. For example, a metasurface 116d configured both as a lens and a beam deflector may formed on a first surface 240 of the monolithic component 238, a metasurface 116e configured both as a beamsplitter and an objective lens may be formed on a second surface 242, and a metasurface 116f configured both as a lens and a beam deflector may be formed on a different area of the first surface 240 (or potentially a different surface). In this configuration, the metasurface 116d may collimate the illumination 106 and direct this collimated illumination 106 to the metasurface 116e for focusing onto the sample 104. The metasurface 116e may then collect sample light 108 and direct this sample light 108 to the metasurface 116f, where the metasurface 116f may operate as a collection-pathway lens 134.

It is contemplated herein that a monolithic component 238 with one or more metasurfaces 116 (e.g., as depicted in FIG. 2D) may provide a robust and highly compact optical head or portion of an optical sub-system 102 more generally.

Referring now to FIG. 2E, FIG. 2E is a schematic diagram of the optical sub-system 102 of FIG. 2A including achromatic metasurfaces 116, in accordance with one or more embodiments of the present disclosure.

As described previously herein, certain designs of a metasurface 116 may provide wavelength-sensitive operation. However, multi-wavelength and/or broadband operation may be achieved using a variety of techniques including, but not limited to, one or more metasurfaces 116 designed to provide multi-wavelength and/or broadband operation directly. For example, a metasurface 116 (or two or more metasurfaces 116 formed in a stack as a compound metasurface 116) may be designed as an achromatic lens that may provide wavelength-corrected optical power over at least a selected wavelength range and within a selected tolerance.

In FIG. 2E, the optical sub-system 102 includes a fused optical element 226b formed from two sub-elements 228e,f. In particular, the fused optical element 226b in FIG. 2E includes a metasurface 116g formed as an achromatic lens and located on a surface 244 to collimate illumination 106, along with a thin-film beamsplitter coating on an interface 246 between the sub-elements 228e,f arranged to form a broadband beamsplitter. A metasurface 116h formed as an achromatic objective lens on another surface 248 may receive a portion of the illumination 106 passing through the interface 246, direct this portion of the illumination 106 to the sample 104, collect sample light 108, and direct this sample light 108 back to the interface 246, where a portion of the sample light 108 may be separated from the illumination 106. A metasurface 116i formed as an achromatic lens may then operate as a collection-pathway lens 134 as described previously herein.

The fused optical element 226b in FIG. 2E further includes an additional surface 250 providing total internal reflection of the sample light 108 prior to the metasurface 116i, which may facilitate desirable positioning of the sample light 108 along the collection pathway 132 towards a detector. However, the particular design of the fused optical element 226b in FIG. 2E including the surface 250 is merely illustrative and should not be interpreted as limiting the scope of the present disclosure. For example, the use of the surface 250 to redirect the sample light 108 is not a requirement. In some embodiments, a surface providing TIR reflection may be implemented to direct any combination of illumination 106 or sample light 108. In some embodiments, a surface providing TIR reflection is not required.

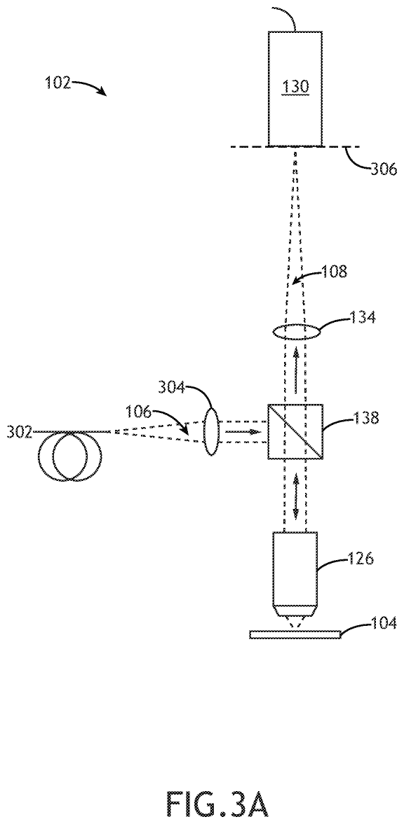

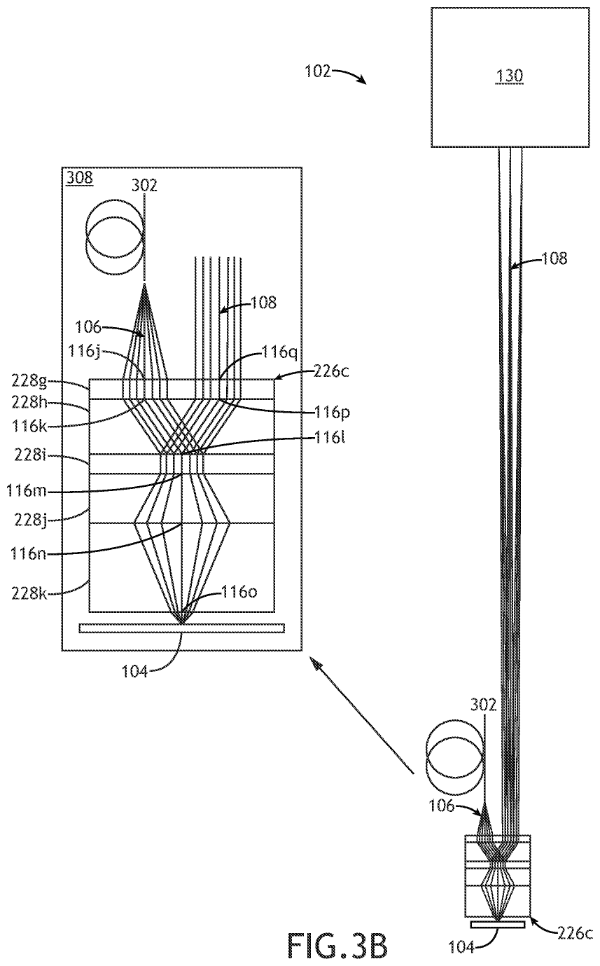

Referring now to FIGS. 3A-3B, FIGS. 3A-3B depict the use of metasurfaces 116 in variations of an optical sub-system 102 suitable for bright-field imaging applications, in accordance with one or more embodiments of the present disclosure. FIG. 3A is a conceptual view of an optical sub-system, in accordance with one or more embodiments of the present disclosure. FIG. 3A is a variation of FIG. 1B such that all descriptions associated with FIG. 1B extend to FIG. 3A. In particular, FIG. 3A depicts a TTL configuration in which incoherent illumination 106 (e.g., multi-wavelength and/or broadband illumination 106) is provided by an optical fiber 302 (e.g., a multi-mode fiber), collimated by a collimator 304, and directed to a sample 104 via a beamsplitter 138 and an objective lens 126. The optical fiber 302 may be associated with the illumination source 118 (e.g., a fiber-based illumination source 118) or may be a delivery fiber. The objective lens 126 collects sample light 108, which passes through the beamsplitter 138 towards one or more detectors 130 located at a field plane 306. The configuration depicted in FIG. 3A may be suitable for, but is not limited to, incoherent bright-field measurement techniques utilizing field-plane detectors 130, non-limiting examples of which are generally described in U.S. patent application Ser. No. 18/422,668 filed on Jan. 25, 2024, which is incorporated herein by reference in its entirety.

FIG. 3B is a schematic diagram of the optical sub-system 102 of FIG. 3A depicted with metasurfaces 116 formed on a fused optical element 226c, in accordance with one or more embodiments of the present disclosure. In particular, the inset 308 in FIG. 3B depicts a detailed view of a fused optical element 226c formed from sub-elements 228g-k, where metasurfaces 116j-q are formed on associated surfaces and/or interfaces. For example, a metasurface 116j formed as a lens (e.g., an achromatic lens) may collimate the illumination 106 and a metasurface 116k formed as a beam deflector (e.g., grating deflector) may direct the collimated illumination 106 to a metasurface 116l formed as a beamsplitter. FIG. 3B further depicts a non-limiting configuration of a multi-surface element formed from multiple metasurfaces 116. In particular, FIG. 3B depicts metasurfaces 116m-o forming a three-surface meta-lens (e.g., a three-surface achromatic objective meta-lens), which may direct the illumination 106 to a sample 104 and collect sample light 108. The metasurface 116l formed as a beamsplitter may then direct at least a portion of the sample light 108 to a metasurface 116p formed as a beam deflector (e.g., grating deflector) and then to a metasurface 116q formed as a lens (e.g., an achromatic lens). This metasurface 116q may correspond to a collection-pathway lens 134 and may facilitate imaging the sample 104 onto the detector 130.

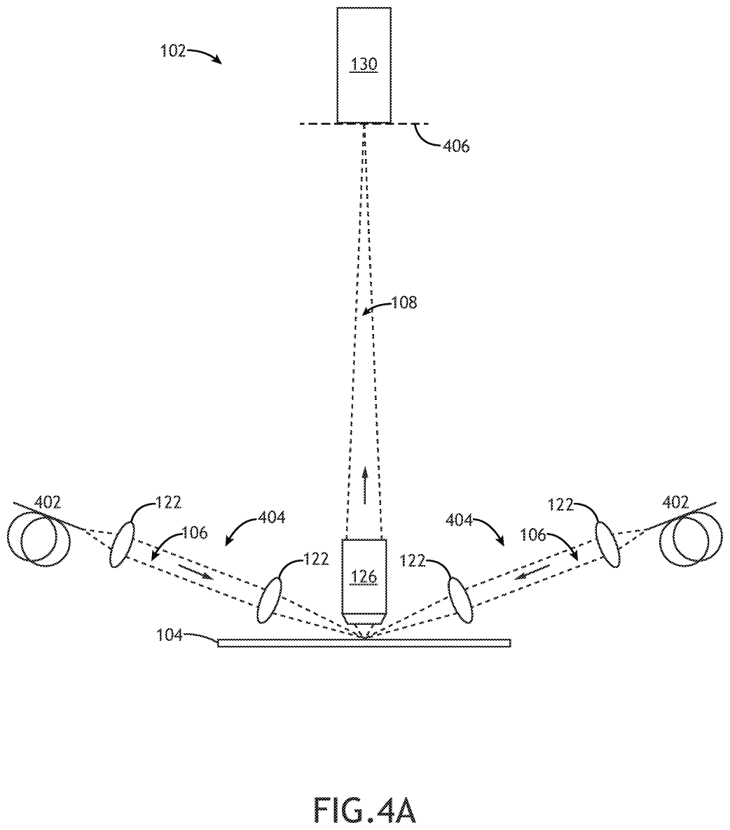

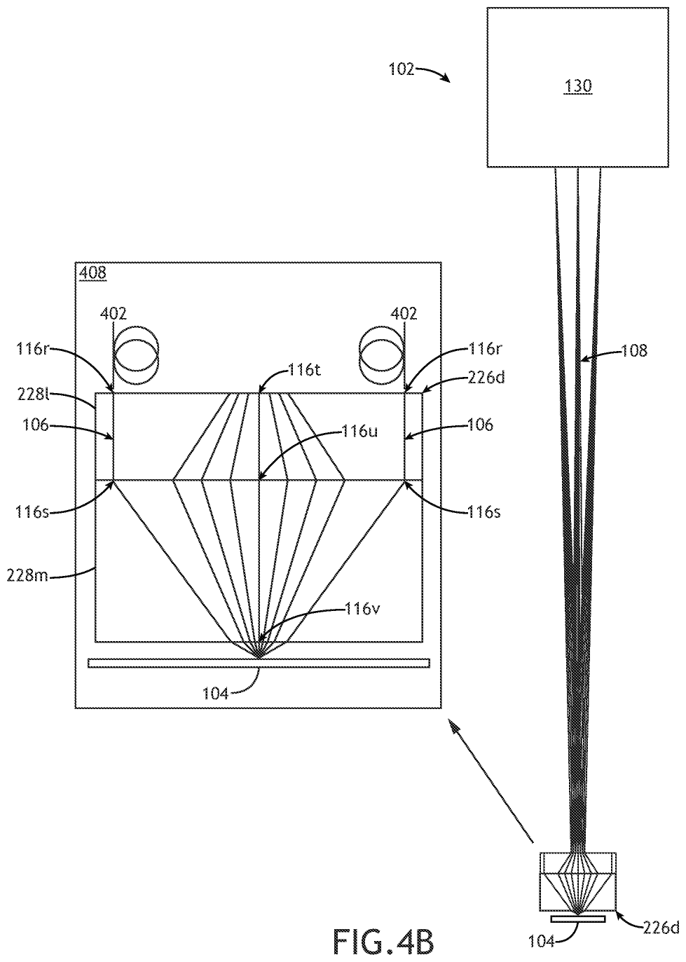

Referring now to FIGS. 4A-4B, FIGS. 4A-4B depict the use of metasurfaces 116 in variations of an optical sub-system 102 suitable for dark-field imaging applications, in accordance with one or more embodiments of the present disclosure. FIG. 4A is a conceptual view of an optical sub-system, in accordance with one or more embodiments of the present disclosure. FIG. 4A is a variation of FIG. 1B such that all descriptions associated with FIG. 1B extend to FIG. 4A. In particular, FIG. 4A depicts an OTL configuration in which illumination 106 (e.g., coherent illumination 106) is provided by an optical fiber 402 (e.g., a single-mode fiber) and directed to a sample via illumination-pathway lenses 122 outside a numerical aperture (e.g., a collection numerical aperture) of an objective lens 126 that is part of the collection pathway 132. Further, multiple beams of illumination 106 may be provided through multiple channels 404. Again, the optical fiber 402 may be associated with the illumination source 118 (e.g., a fiber-based illumination source 118) or may be a delivery fiber. The objective lens 126 collects sample light 108, where one or more detectors 130 located at a field plane 406 generate one or more dark-field images of the sample 104 based on collected sample light 108 (e.g., which does not include specular reflection of the illumination 106 that is also outside the collection numerical aperture of the objective lens 126). The configuration depicted in FIG. 4A may be suitable for, but is not limited to, coherent dark-field measurement techniques utilizing field-plane detectors 130, non-limiting examples of which are generally described in U.S. Pat. No. 11,359,916 issued on Jun. 14, 2022, and U.S. Patent Publication No. 2023/0259040 published on Aug. 17, 2023, which are all incorporated herein by reference in their entireties.

FIG. 4B is a schematic diagram of the optical sub-system 102 of FIG. 4A depicted with metasurfaces 116 formed on a fused optical element 226d, in accordance with one or more embodiments of the present disclosure. In particular, inset 408 of FIG. 4B depicts a fused optical element 226d formed from sub-elements 228l,m, where metasurfaces 116r-v are formed on associated surfaces and/or interfaces. For example, a metasurface 116r formed as a lens may collimate the illumination 106 and a metasurface 116s formed as a beam deflector (e.g., grating deflector) may direct the collimated illumination 106 towards the sample 104. Further, multiple instances of the metasurfaces 116r,s may provide multiple beams of illumination 106. FIG. 4B further depicts metasurfaces 116t-v formed as a three-surface meta-lens (e.g., a three-surface objective meta-lens), which may collect the sample light 108 as shown.

In a manner similar to the examples provided in FIGS. 2A-2E, FIGS. 3A-4B depict the use of metasurfaces 116 in an optical sub-system 102 (or a portion thereof such as an optical head), which may enable robust performance in a highly-compact package. However, it is to be understood that FIGS. 3A-4B are provided solely for illustrative purposes and should not be interpreted as limiting the scope of the present disclosure. For example, the optical sub-system 102 (or a portion thereof) may be formed using any number of metasurfaces 116 on any number of surfaces. As another example, the optical sub-system 102 may be extended to include one or more metasurfaces 116 providing multiple optical functions (e.g., optical power, diffraction, refraction, or the like). As another example, the optical sub-system 102 may include one or more metasurfaces 116 on any combination of bulk optical elements, fused components, and/or monolithic components. As another example, the depiction of a three-surface objective meta-lens in FIGS. 3B and 4B is merely illustrative. More generally, any number of metasurfaces 116 may be arranged on any number of surfaces to provide a desired optical function.

Additionally, FIGS. 2A-4B, the associated configurations of the optical sub-system 102, and/or the associated application areas are also provided solely for illustrative purposes and should not be interpreted as limiting. More generally, an optical measurement system 100 may include an optical sub-system 102 having any design suitable for any type of optical measurements of a sample 104, where the optical sub-system 102 includes at least one metasurface 116.

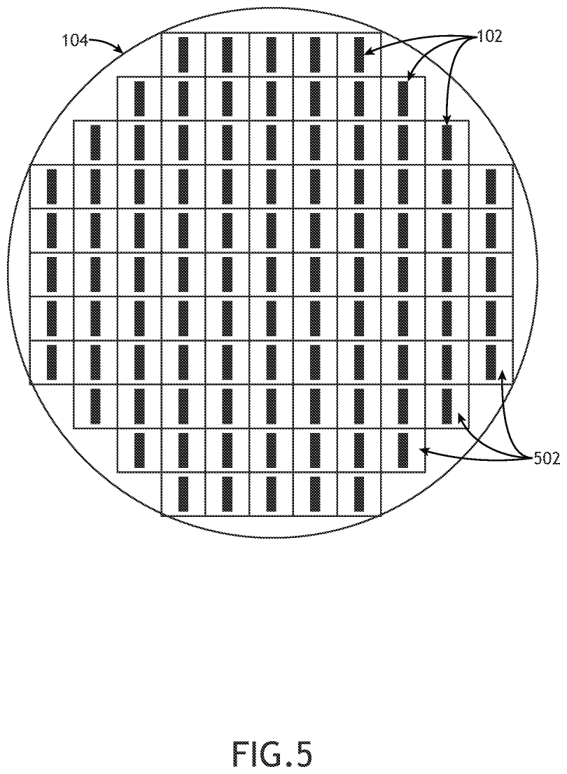

Referring now to FIG. 5, multi-channel optical measurements using multiple optical sub-systems 102 incorporating metasurfaces 116 is described in greater detail, in accordance with one or more embodiments of the present disclosure. In some embodiments, an optical measurement system 100 includes two or more optical sub-systems 102, where at least one of the optical sub-systems 102 includes one or more metasurfaces 116. As described previously herein, the use of one or more metasurfaces 116 may enable a substantial reduction in the physical size of an optical sub-system 102 (or a portion thereof such as an optical head). As a result, multiple optical sub-systems 102 (or portions thereof such as optical heads) may be distributed to provide parallel (and optionally simultaneous) measurements of different portions of a sample 104.

FIG. 5 is a conceptual schematic depicting an arrangement of multiple optical sub-systems 102 across a sample 104 for parallel measurements, in accordance with one or more embodiments of the present disclosure. Massive overlay metrology sampling is described generally in U.S. Pat. No. 11,899,375 issued on Feb. 13, 2024, which is incorporated herein by reference in its entirety. In particular, FIG. 5 depicts a configuration in which a separate optical sub-system 102 is provided for each reticle field 502 associated with a lithography tool (e.g., a scanner, a stepper, or the like) used to fabricate features on the sample 104. In this way, separate optical sub-systems 102 may be used to provide parallel measurements of features associated with different dies on the sample 104. Further, such a configuration may utilize a separate detector 130 for each optical sub-system 102, or multiple optical sub-systems 102 may share a common detector 130. However, it is to be understood that FIG. 5 is provided solely for illustrative purposes and should not be interpreted as limiting the scope of the present disclosure. Rather, an optical measurement system 100 may include any number of optical sub-systems 102, where at least one of the optical sub-systems 102 includes one or more metasurfaces 116.

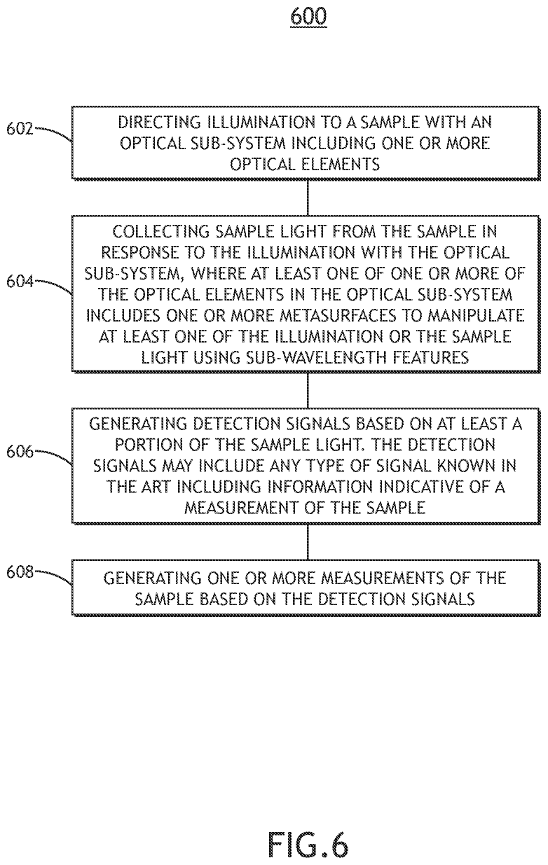

FIG. 6 is a flow diagram illustrating steps performed in a method 600 for providing an optical measurement, in accordance with one or more embodiments of the present disclosure. The embodiments and enabling technologies described previously herein in the context of the optical measurement system 100 should be interpreted to extend to the method 600. For example, the processors 112 of the controller 110 may execute program instructions causing the processors 112 to perform various steps of the method 600 directly or indirectly (e.g., via control signals to additional components). It is further noted, however, that the method 600 is not limited to the architecture of the optical measurement system 100.

In some embodiments, the method 600 includes a step 602 of directing illumination 106 to a sample 104 with an optical sub-system 102 including one or more optical elements.

In some embodiments, the method 600 includes a step 604 of collecting sample light 108 from the sample 104 in response to the illumination 106 with the optical sub-system 102, where at least one of one or more of the optical elements in the optical sub-system 102 includes one or more metasurfaces 116 to manipulate at least one of the illumination 106 or the sample light 108 using sub-wavelength features. The sub-wavelength features may be smaller than at least some wavelengths in at least one of the illumination 106 or the sample light 108.

In some embodiments, the method 600 includes a step 606 of generating detection signals based on at least a portion of the sample light 108. The detection signals may include any type of signal known in the art including information indicative of a measurement of the sample 104. For example, detection signals may include, but are not limited to, field-plane images of a sample 104 from a detector 130 at a field plane, pupil-plane images associated with a distribution of light emanating from the sample 104 (e.g., diffracted light), or time-based signals associated with pupil-plane and/or field-plane detectors 130 (e.g., photodiodes). In some embodiments, the method 600 includes a step 608 of generating one or more measurements of the sample 104 based on the detection signals. The measurements may include any type of information associated with the sample 104. In some embodiments, a measurement includes a metrology measurement such as, but not limited to, an overlay measurement or a critical dimension (CD) measurement. In some embodiments, a measurement includes an inspection measurement such as, but not limited to, identifying and/or characterizing defects on the sample 104.

Referring now generally to FIGS. 1-6, additional considerations of metasurfaces 116 within an optical measurement system 100 are described, in accordance with one or more embodiments of the present disclosure.

It is contemplated herein that metasurfaces 116 may provide numerous advantages or traditional optical elements.

For example, metasurfaces 116 may enable small and/or flat optical components, which may reduce a size of an optical head (e.g., an optical sub-system 102), which in turn enables such optical heads to be more closely packed such that multiple parallel measurements per sample 104 are enabled. Further, metasurfaces 116 may be integrated into one or more substrates of an optical element (e.g., a bulk, fused, or monolithic optical element) and/or combined (e.g., stacked) as disclosed herein to enable dense integration and small overall component size.

As another example, metasurfaces 116 may enable relatively short focal lengths (e.g., when used to form an objective lens 126), which may allow for high numerical apertures (e.g., greater than or equal to 0.7, 0.93, or higher).

As another example, metasurfaces 116 may be relatively cost-effective to fabricate and assemble. As an illustration, metasurfaces 116 may be fabricated using efficient high-volume manufacturing processes such as, but not limited to, semiconductor manufacturing processes. As another illustration, optical components fabricated with metasurfaces 116 may require fewer mechanical parts for mounting, particularly when multiple metasurfaces 116 are integrated into bulk, fused, or monolithic components as described herein. Further, when multiple metasurfaces 116 are integrated into bulk, fused, or monolithic components, such metasurfaces 116 may be aligned during fabrication such that alignment and/or assembly of the optical sub-system 102 may be easier, faster, and/or may require fewer mechanical parts.

As another example, metasurfaces 116 may be fabricated with a high consistency and/or reliability. For example, semiconductor manufacturing processes used to fabricate metasurfaces 116 may be tightly controlled and in some cases more tightly controlled than fabrication processes for traditional optical components.

As another example, metasurfaces 116 may be combined with traditional optical elements (e.g., refractive, reflective, and diffractive elements or surfaces) within an optical head (e.g., an optical sub-system 102). Further, multiple metasurfaces 116 on different surfaces may work together to provide a multi-surface element. As an illustration, an objective lens 126 may be formed from one or more metasurfaces 116 on any number of surfaces. As another illustration, an objective lens 126 may be formed from a combination of one or more metasurfaces 116 with refractive, reflective, and/or diffractive elements or surfaces. In some embodiments, an objective lens with at least one or more metasurfaces 116 may be designed to operate with a finite conjugate to directly generate an image or other distribution on a detector 130 such that an additional collection lens (e.g., a collection-pathway lens 134) is not necessary.

As another example, metasurfaces 116 may be designed to support multiple wavelengths either directly or by stacking multiple metasurfaces 116. In this way, a user may select a wavelength or wavelength range for operation. As another example, different optical heads (e.g., different optical sub-systems 102) within a single optical measurement system 100 may be designed to support different wavelengths.

As another example, metasurfaces 116 may be used in polarization-sensitive applications. For instance, one or more metasurfaces 116 may directly manipulate the polarization of light (e.g., illumination 106 and/or sample light 108). As an illustration, one or more metasurfaces 116 may operate as a polarizer, a waveplate, or a polarization manipulator more generally). In another instance, one or more metasurfaces 116 may provide polarization-sensitive operation. In this configuration, an optical sub-system 102 may include a polarizer and/or polarization manipulator prior to a polarization-sensitive metasurface 116.

As another example, metasurfaces 116 alone or in combination with refractive, reflective and/or diffractive elements or surfaces may be used to shape a beam profile of light (e.g., illumination 106 and/or sample light 108). In this configuration, such components may operate instead of or in addition to apodization or truncation components. Further, such a configuration may conserve light through beam shaping rather than filtering.

Additionally, any components of an optical sub-system 102 including a metasurface 116 or other component may be tilted or wedged to deflect stray light out of the optical path.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A device, comprising:
one or more optical elements configured to direct illumination to a sample and collect sample light from the sample in response to the illumination, wherein at least one of the one or more optical elements include one or more metasurfaces configured to manipulate at least one of the illumination or the sample light using sub-wavelength features, wherein the sub-wavelength features are smaller than at least some wavelengths in at least one of the illumination or the sample light being manipulated, wherein the one or more optical elements provide optical power for at least one of focusing the illumination on the sample or collecting the sample light from the sample.

2. The device of claim 1, wherein at least one of the one or more metasurfaces comprises:
a lens.

3. The device of claim 1, wherein at least one of the one or more metasurfaces comprises:
a beamsplitter.

4. The device of claim 1, wherein at least one of the one or more metasurfaces comprises:
one or more beam deflectors.

5. The device of claim 1, wherein at least one of the one or more metasurfaces comprises:
an objective lens.

6. The device of claim 5, wherein the objective lens is a multi-surface element formed from at least two metasurfaces of the one or more metasurfaces.

7. The device of claim 1, wherein the one or more optical elements include one or more bulk optical elements, wherein at least one of the one or more metasurfaces is formed on a surface of at least one of the one or more bulk optical elements.

8. The device of claim 7, wherein the one or more metasurfaces include two or more metasurfaces, wherein at least one of the one or more bulk optical elements includes at least two of the two or more metasurfaces.

9. The device of claim 1, wherein the one or more optical elements include one or more fused optical elements formed from two or more sub-elements, wherein at least one of the one or more metasurfaces is formed at an interface of two of the two or more sub-elements.

10. The device of claim 9, wherein the one or more metasurfaces include two or more metasurfaces, wherein at least one of the one or more fused optical elements includes at least two of the two or more metasurfaces.

11. The device of claim 1, wherein the one or more optical elements comprise:
a first lens formed as at least one of the one or more metasurfaces and configured to collimate the illumination, wherein the illumination is incident on the first lens as a diverging beam;
an objective lens formed as at least one of the one or more metasurfaces, wherein the objective lens is configured to direct the illumination to the sample and collect the sample light from the sample;
a first grating configured to direct the illumination from the first lens to the objective lens;
a second lens formed as at least one of the one or more metasurfaces; and
a second grating to receive the sample light from the objective lens and direct the sample light to the second lens.

12. The device of claim 11, wherein the first lens, the objective lens, the first grating, the second lens, and the second grating are integrated in a fused optical element.

13. The device of claim 1, wherein the one or more optical elements comprise:
an objective lens formed as one of the one or more metasurfaces, wherein the objective lens is configured to direct the illumination to the sample and collect the sample light from the sample;
a first metasurface of the one or more metasurfaces configured collimate the illumination and direct the illumination to the objective lens, wherein the illumination is incident on the first metasurface as a diverging beam; and
a second metasurface of the one or more metasurfaces configured to receive the sample light from the objective lens and focus the sample light.

14. The device of claim 13, wherein the second metasurface focuses the sample light to a collection field stop.

15. The device of claim 13, wherein the objective lens, the first metasurface, and the second metasurface are integrated in a monolithic element.

16. The device of claim 1, wherein the one or more optical elements comprise:
an objective lens formed as at least one of the one or more metasurfaces, wherein the objective lens is configured to direct the illumination to the sample and collect the sample light from the sample;
a first metasurface of the one or more metasurfaces configured collimate the illumination, wherein the illumination is incident on the first metasurface as a diverging beam;
a second metasurface; and
a beamsplitter configured to direct the illumination from the first metasurface to the objective lens and direct the sample light from the objective lens to the second metasurface, wherein the second metasurface focuses the sample light.

17. The device of claim 16, wherein the second metasurface focuses the sample light to a collection field stop.

18. The device of claim 16, wherein the objective lens, the first metasurface, the second metasurface, and the beamsplitter are integrated in a fused optical element.

19. The device of claim 18, wherein the fused optical element further includes a surface to direct the sample light through from the beamsplitter to the second metasurface via total internal reflection.

20. The device of claim 1, wherein the one or more optical elements comprise:
an objective lens formed as at least one of the one or more metasurfaces, wherein the objective lens is configured to collect the sample light from the sample; and
at least one of the one or more metasurfaces configured to direct the illumination to the sample at an angle outside a numerical aperture of the objective lens.

21. The device of claim 20, wherein the at least one of the one or more metasurfaces configured to direct the illumination to the sample at an angle outside a numerical aperture of the objective lens directs two or more beams of the illumination to the sample outside the numerical aperture of the objective lens.

22. The device of claim 1, wherein at least some of the sub-wavelength features in at least one particular metasurface of the one or more metasurfaces are arranged into islands distributed across the particular metasurface.

23. The device of claim 22, wherein at least one of the sub-wavelength features within the islands, a spacing between the islands, or an orientation of the islands varies across the particular metasurface.

24. The device of claim 1, wherein a distribution of the sub-wavelength features in at least one particular metasurface of the one or more metasurfaces is uniform across the particular metasurface.

25. The device of claim 1, wherein at least some of the sub-wavelength features in at least one of the one or more metasurfaces are formed as a blazed feature.

26. The device of claim 1, wherein at least some of the sub-wavelength features in at least one of the one or more metasurfaces are formed as a grating feature.

27. The device of claim 1, wherein at least some of the sub-wavelength features in at least one of the one or more metasurfaces are formed as a stepped feature.

28. The device of claim 1, wherein the one or more metasurfaces include two or more metasurfaces, wherein at least two of the two or more metasurfaces are formed as a stacked structure.

29. The device of claim 1, wherein at least one of the one or more metasurfaces directs the illumination to the sample at an angle associated with a numerical aperture of at least 0.7.

30. A metrology system, comprising:
an illumination source configured to generate illumination;
one or more optical sub-systems, wherein a respective one of the one or more optical sub-systems includes one or more optical elements configured to direct the illumination to a sample and collect sample light from the sample in response to the illumination, wherein at least one of the one or more optical elements includes one or more metasurfaces configured to manipulate at least one of the illumination or the sample light using sub-wavelength features, wherein the sub-wavelength features are smaller than at least some wavelengths in at least one of the illumination or the sample light, wherein the one or more optical elements provide optical power for at least one of focusing the illumination on the sample or collecting the sample light from the sample;
a one or more detectors configured to generate detection signals based on the sample light collected by the one or more optical sub-systems; and
a controller communicatively coupled to the one or more detectors, wherein the controller includes one or more processors configured to execute program instructions stored in a memory device, wherein the program instructions are configured to cause the one or more processors to execute a metrology recipe by generating a plurality metrology of measurements of the sample based on the detection signals from the one or more detectors.

31. The metrology system of claim 30, wherein the one or more optical sub-systems comprise two or more optical sub-systems.

32. The metrology system of claim 31, wherein a distribution of the two or more optical sub-systems is arranged to provide parallel measurements of features in one or more fields on the sample.

33. The metrology system of claim 32, wherein the distribution of the two or more optical sub-systems is arranged to provide a single one of the two or more optical sub-systems for at least one of the one or more fields on the sample.

34. The metrology system of claim 32, wherein the distribution of the two or more optical sub-systems is arranged to provide at least two of the two or more optical sub-systems for at least one of the one or more fields on the sample.

35. The metrology system of claim 30, wherein at least one of the one or more metasurfaces comprises:
a lens.

36. The metrology system of claim 30, wherein at least one of the one or more metasurfaces comprises:
a beamsplitter.

37. The metrology system of claim 30, wherein at least one of the one or more metasurfaces comprises:
one or more beam deflectors.

38. The metrology system of claim 30, wherein at least one of the one or more metasurfaces comprises:
an objective lens.

39. The metrology system of claim 38, wherein the objective lens is formed from at least two metasurfaces of the one or more metasurfaces.

40. The metrology system of claim 30, wherein the one or more optical elements include one or more bulk optical elements, wherein at least one of the one or more metasurfaces is formed on a surface of at least one of the one or more bulk optical elements.

41. The metrology system of claim 40, wherein the one or more metasurfaces include two or more metasurfaces, wherein at least one of the one or more bulk optical elements includes at least two of the two or more metasurfaces.

42. The metrology system of claim 30, wherein the one or more optical elements include one or more fused optical elements formed from two or more sub-elements, wherein at least one of the one or more metasurfaces is formed at an interface of two of the two or more sub-elements.

43. The metrology system of claim 42, wherein the one or more metasurfaces include two or more metasurfaces, wherein at least one of the one or more fused optical elements includes at least two of the two or more metasurfaces.

44. The metrology system of claim 30, wherein the one or more optical elements include a single monolithic element.

45. A metrology method, comprising:
directing illumination to a sample with an optical sub-system including one or more optical elements;
collecting sample light from the sample in response to the illumination with the optical sub-system, wherein at least one of the one or more optical elements includes one or more metasurfaces configured to manipulate at least one of the illumination or the sample light using sub-wavelength features, wherein the sub-wavelength features are smaller than at least some wavelengths in at least one of the illumination or the sample light, wherein the one or more optical elements provide optical power for at least one of focusing the illumination on the sample or collecting the sample light from the sample;
generating detection signals based on at least a portion of the sample light; and
generating one or more metrology measurements of the sample based on the detection signals.
